(19) United States
(12) Patent Application Publication
(10) Pub. No.: US 2016/0133695 A1
(43) Pub. Date: May 12, 2016

(54) A METHOD OF INHIBITING LEAKAGE CURRENT OF TUNNELING TRANSISTOR, AND THE CORRESPONDING DEVICE AND A PREPARATION METHOD THEREOF

(71) Applicant: PEKING UNIVERSITY, Beijing (CN)

(72) Inventors: Ru Huang, Beijing (CN); Qianqian Huang, Beijing (CN); Chunlei Wu, Beijing (CN); Jiaxin Wang, Beijing (CN); Chao Wang, Beijing (CN); Yangyuan Wang, Beijing (CN)

(73) Assignee: PEKING UNIVERSITY, Beijing (CN)

(21) Appl. No.: 14/893,870

(22) PCT Filed: Jan. 9, 2014
(86) PCT No.: PCT/CN2014/070364

§ 371 Date: Nov. 24, 2015

(30) Foreign Application Priority Data
Nov. 13, 2013 (CN) 201310571563.1

(51) Int. Cl. H01L 29/06; H01L 29/08; H01L 29/10; H01L 21/265; H01L 21/3213; H01L 21/308; H01L 21/02; H01L 21/266; H01L 29/78; H01L 29/66

(52) U.S. Cl. CPC H01L 29/0638; H01L 29/7835; H01L 29/0847; H01L 29/1033; H01L 29/66659; H01L 29/0649; H01L 21/32139; H01L 21/308; H01L 21/02238; H01L 21/266; H01L 21/26513

(57) ABSTRACT

Provided are a method for suppressing a leakage current of a tunnel field-effect transistor (TFET), a corresponding device, and a manufacturing method, related to the field of field-effect transistor logic devices and circuits in CMOS ultra large-scale integration (ULSI). By inserting an insulating layer (7) between a source region (10) and a transistor body below a tunneling junction, and by inserting no insulating layer at a tunneling junction between a source region and a channel, a source/drain direct tunneling leakage current in a small-sized TFET device is effectively suppressed, and a threshold slope is effectively improved. The manufacturing method for the corresponding device is completely compatible with an existing CMOS process.

The present application claims priority of Chinese Patent Application (No. 201310571563.1) filed on Nov. 13, 2013, which is incorporated herein by reference in its entirety.

### TECHNICAL FIELD

The invention belongs to a field of a field effect transistor logic device and the circuit in connection with CMOS ultra large scale integrated circuit (ULSI), and particularly refers to a method of inhibiting tunneling transistor leakage current, and the corresponding device and a preparation method thereof.

### BACKGROUND OF THE INVENTION

Under the drive of Moore's Law, the feature size of the conventional MOSFET continually shrink and now has progressed to the nanometer scale, consequently, the negative effects such as short channel effect of a device and so on have become more serious. The effects such as drain induced barrier lowering, band-to-band tunneling and so on cause a off-state leakage current of a device to increase continually, and at the same time, a sub-threshold slope of the conventional MOSFET can not decrease synchronously with the shrink of the device size due to the limitation by the thermal potential, and thereby the device power consumption increases. Now the power consumption concern has become the most serious problem of limiting the device shrink.

In order to enable the device to be applied in the field of ultra-low voltage and low power consumption, achievement of a device structure with ultra-steep sub-threshold slope based on a new turn-on mechanism and a process and preparation method thereof have become the focus drawing everyone's attentions to small size devices. In recent years, researchers have proposed a possible solution of using tunneling field effect transistor (TFET). Not like the conventional MOSFET, TFET has source and drain with opposite doping types each other, can control the band-to-band tunneling of the reverse biased PIN junction by gate to achieve turn-on, can break through the limitation of the sub-threshold slope 60 mV/dec of the conventional MOSFET, and has a very small leakage current in the cases of long channel. TFET has many advantages such as low leakage current, low sub-threshold slope, low operating voltage and low power consumption, and so on. However, due to the limitation of source junction tunneling probability and tunneling area, TFET is faced with an issue of small on-state current, which greatly limits the applications of TFET devices. In addition, for small size TFET, when the gate length is less than about 20 nm, the direct band-to-band tunneling current from source to drain in bulk region may increase sharply, so that the leakage current and sub-threshold slope of TEFT devices degrade seriously. TFET adopting ultra-thin bulk SOI substrate can inhibit this short channel effect in some extent, but due to the presence of the buried oxide layer under thin silicon film, thermal dissipation problem will become a major issue that the self-heating effect is serious, which affects the device characteristics, and at the same time the requirements of thin silicon film also increase the process complexity of the device.

### SUMMARY OF THE INVENTION

The purpose of the present invention is to provide a method of inhibiting a leakage current of a tunneling transistor, and the corresponding device and a preparation method thereof. The method may inhibit effectively the leakage current from source-to-drain direct tunneling in the small size TEFT device while improving effectively the sub-threshold slope by interposing an insulating layer between a source region and a bulk region under a tunneling junction and no insulating layer in the tunneling junction between the source region and a channel. The preparation method of the corresponding device is fully compatible with the existing CMOS process.

The technical solutions of the present invention are provided as follows.

A tunneling transistor according to the present invention includes a high resistance semiconductor substrate (1), a highly-doped source region (10), a lowly-doped drain region (11), a gate dielectric layer (3) and a control gate (4). A tunneling junction of the tunneling transistor is formed between the highly-doped source region (10) and channel and has a thickness h of 5-10 nm, and an insulating layer (7) is provided between the highly-doped source region (10) and the high resistance semiconductor substrate (1) under the tunneling junction and has a thickness of 50-500 nm. The doped source region and the doped drain region are disposed on both sides of the control gate, respectively, and have the doping types opposite to each other and different doping concentrations from each other. For the N-type transistor, the source region is a highly-doped P⁺ source region and has a doping concentration between 5×10¹⁹ cm⁻³ and 1×10²¹ cm⁻³, and the drain region is a lowly-doped N drain region and has a doping concentration between 1×10¹⁸ cm⁻³ and 1×10¹⁹ cm⁻³. For a P-type transistor, the source region is a highly-doped N⁺ source region and has a doping concentration between 5×10¹⁹cm⁻³ and 1×10²¹cm⁻³, and the drain region is a lowly-doped P drain region and has a doping concentration between 1×10¹⁸cm⁻³ and 1×10¹⁹cm⁻³. The high resistance semiconductor is lightly doped, with the same doping type as that of the source region, and has a doping concentration less than 1×10¹⁷cm⁻³.

A preparation method of the tunneling transistor described above comprises the steps of:

(1) defining an active region by shallow trench isolation in a high resistance semiconductor substrate;

(2) growing a gate dielectric layer, and depositing a control gate material and a hard mask layer;

(3) performing photolithography and etching to form a pattern for control gate, and using sidewall process to form a layer of thin sidewall protection structure, wherein a thickness of the thin sidewall determines the distance from a source junction to the edge of the control gate depending on the design;

(4) exposing a source region by photolithography, anisotropically etching, with an etching depth as a thickness h of the tunneling junction, the silicon in the source region using a gate sidewall as a protection layer; then depositing an oxidation resistant material, performing photolithography to expose the source region again, anisotropically etching the oxidation resistant material to form a single side oxidation resistant sidewall;

(5) further anisotropically etching the silicon in the source region to form a recessed silicon trench structure using the oxidation resistant sidewall for protection; oxidizing the exposed silicon to form an insulating layer;

(6) removing an oxidation resistant layer, then depositing a source material, and overetching the source material till the surface of a channel;

(7) exposing the source region by photolithography, and forming a highly-doped source region by performing ion implantation using photoresist and the control gate as a mask; then exposing the drain region by photolithography, and forming a lowly-doped drain region with the other doping type by performing ion implantation using photoresist and the control gate as a mask; and then performing rapid high temperature thermal annealing to activate the doped impurities for source/drain;

(8) finally proceeding to a general CMOS Back-End-Of-Line, comprising depositing a passivation layer, opening contact holes and performing metallization, so that the tunneling field effect transistor is prepared, as shown in FIG. 8.

In the preparation method described above, a material for the semiconductor substrate in the step (1) is selected from a group consisting of Si, Ge, SiGe, GaAs, and the other binary or ternary compound semiconductor in II-VI, III-V and IV-IV groups, silicon on insulator (SOI) and germanium on insulator (GOI).

In the preparation method described above, a material for the gate dielectric layer in the step (2) is selected from a group consisting of SiO₂, Si₃N₄, and high-K gate dielectric material.

In the preparation method described above, growing of the gate dielectric layer in the step (2) is performed by a process selected from a group consisting of: general thermal oxidation, nitrogen-doped thermal oxidation, chemical vapor deposition and physical vapor deposition.

In the preparation method described above, the control gate material in the step (2) is selected from a group consisting of doped polysilicon, metal cobalt, nickel and the other metal or metal silicide.

In the preparation method described above, a material for the thin sidewall in the step (3) is oxide such as SiO₂ and so on.

In the preparation method described above, the oxidation resistant material in the step (4) is a dysoxidizable material such as Si₃N₄ and so on.

In the preparation method described above, the source/drain material in the step (6) is selected from a group consisting of polysilicon, Ge, SiGe, GaAs, and the other binary or ternary compound semiconductor in II-VI, III-V and IV-IV groups.

The method of inhibiting a leakage current of a tunneling transistor specially comprise the following steps: providing an insulating layer under a tunneling junction of a tunneling transistor, where the insulating layer is disposed between a source region and a bulk region under a channel, so that the leakage current from source-to-drain direct tunneling of the tunneling transistor is inhibited using the insulating layer.

The present invention has the technical effects as follows:

Firstly, the method of the present invention may decrease effectively a small size

TFET device's probability of direct band-to-band tunneling from the source to the drain by introduction of an insulating layer under a tunneling junction, thereby inhibiting a tunneling leakage current of the tunneling transistor and obtaining a lower off-state current. Furthermore, an electric field centralization effect of the insulating layer enables the device to obtain a higher electric field than the traditional TFET when the band-to-band tunneling occurs, thereby improving sub-threshold characteristics of the TFET device.

Secondly, the tunneling transistor prepared by the method of the present invention has a highly-doped source region and a lowly-doped drain region, wherein the source region has a doping concentration between 5×10¹⁹cm⁻³ and 1×10²¹cm⁻³, the drain region has a doping concentration between 1×10¹⁸cm⁻³ and 1×10¹⁹cm⁻³, and the doping type of the source region is opposite to that of the drain region, the substrate is lightly doped, with a doping type being same as the doping type of the source region, and has a doping concentration less than 1×10¹⁷cm⁻³. The transistor can turn on using the band-to-band tunneling mechanism in connection with the tunneling junction, and can break through the limitation of the sub-threshold slope of the MOSFET to obtain the steeper sub-threshold characteristics than the conventional TEFT device and MOSFET device. The low concentration doping for drain region can also reduce effectively the probability of band-to-band tunneling in the drain junction so as to inhibit the tunneling current in the drain junction, and thereby can inhibit an ambipolar effect of the device. In addition, because the semiconductor substrate of the tunneling transistor of the present invention is lightly doped and the doping type thereof is the same as the doping type of the source, the tunneling transistor is a three-terminal device where the substrate is biased directly via the source junction, and can obtain a smaller layout area and a higher integration density compared with a MOSFET as a four-terminal device. Moreover, the tunneling transistor of present invention can solve effectively the issue of thermal dissipation of SOI structure to inhibit the self-heating effect compared with the conventional SOI TFET structure.

Thirdly, the preparation method of the corresponding tunneling transistor in connection with the method of the present invention is fully compatible with the conventional CMOS process. The thickness of the tunneling junction is determined by the etching process, and thus the requirement for a thin film process is relieved compared with SOI TFET structure. Furthermore, in the preparation method, lastly depositing of the source material can facilitate to the design for hetero-junction of TFET and can accurately control the location of the hetero-junction of TFET. The hetero-junction TFET has a steeper tunneling junction and a smaller tunneling barrier width compared with homo-junction TFET, so the device can obtain a higher turn-on current and a steeper sub-threshold slope.

In short, the method of the present invention can inhibit effectively the leakage current from source-to-drain direct tunneling of TFET in the small size, and on the other hand can also obtain a larger tunneling electric field, and thereby improve the sub-threshold characteristic of TFET device. The tunneling transistor prepared by using this method may also inhibit the ambipolar effect of the device, has a smaller layout area and a higher integration density, and the preparation process is fully compatible with the existing CMOS process, and thus the device can be expected to be applied in the field of the low power consumption and has a higher practical value.

### BRIEF DESCRIPTION OF THE DRAWINGS

FIG. 1 is a schematic diagram of a process step for forming a shallow trench isolation on a high resistance semiconductor substrate;

FIG. 2 is a schematic diagram of a device after a gate dielectric layer is grown and a control gate and a thin sidewall are formed;

FIG. 3 is a schematic diagram of the device after silicon on the source region is etched by a thickness h and a single side oxidation resistant sidewall is formed;

FIG. 4 is a schematic diagram of the device after a groove for the source region is formed by performing etching and an insulating layer with “L” shape is formed by performing oxidization;

FIG. 5 is a schematic diagram of the device after a source material is deposited;

FIG. 6 is a schematic diagram of the device after the source region is exposed by photolithography and then a highly-doped source region is formed by performing ion implantation;

FIG. 7 is a schematic diagram of the device after the drain region is exposed by photolithography and then a lowly-doped drain region with the other doping type is formed by performing ion implantation;

FIG. 8 is a schematic diagram of the tunneling transistor after depositing a passivation layer, opening contact holes and performing metallization.

In the drawings:

```
  1 - a high resistance semiconductor substrate
  2 - an isolation layer for active region
```

| | |
|---|---|
| 3 - a gate dielectric layer | 4 - a control gate |
| 5 - a gate hard mask layer | 6 - an oxidation resistant sidewall |
| 7 - an insulating layer | 8 - source material |
| 9 - photoresist | 10 - a highly-doped source region |
| 11 - a lowly-doped drain region | 12 - a passivation isolation layer |
| 13 - a metal layer | |

### DETAILED DESCRIPTION OF THE EMBODIMENTS

Hereinafter, the present invention will be further described with respect to the examples. It is noted that, the embodiments are provided so that this disclosure will be thorough and complete, and will fully convey the scope of the present invention to those skilled in the art, and it will be appreciated to those skilled in the art that various changes and modifications may be made without departing from the spirit and scope defined by the present invention and the accompanying claims. Accordingly, the present invention should not be construed as being limited to the embodiments, and the protected scope of the present invention should be defined by the claims.

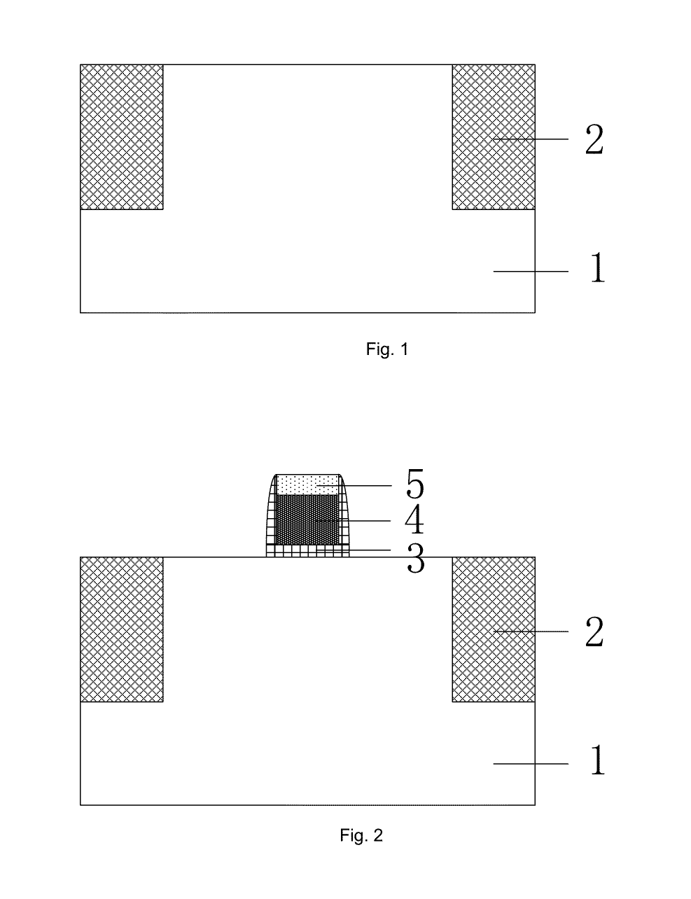

A specific example of the preparation method according to the present invention includes the process steps shown in FIG. 1 to FIG. 8:

1. Selecting a bulk silicon wafer with a crystal orientation (100) as a silicon substrate 1, forming an isolation layer 2 for active region on the silicon substrate 1 using a shallow trench isolation technology, wherein the silicon substrate is lightly doped with respect to a doping concentration, as shown in FIG. 1.

2. Then thermally growing a gate dielectric layer 3, wherein the gate dielectric layer is SiO₂ and has a thickness of 1-5 nm; depositing a gate electrode layer 4 and a gate hard mask layer 5, wherein the gate electrode layer is a doped polysilicon layer and has a thickness of 150-300 nm, and the hard mask layer is SiO₂ and has a thickness of 100-200 nm; defining a pattern for control gate by photolithography, and etching the gate hard mask layer 5 and the gate electrode layer 4 till the gate dielectric layer 3; depositing a thin layer of SiO₂, with a thickness of 30 nm, using LPCVD process to cover a gate structure, and then forming the gate structure with thin sidewalls for protection using a dry etching, as shown in FIG. 2.

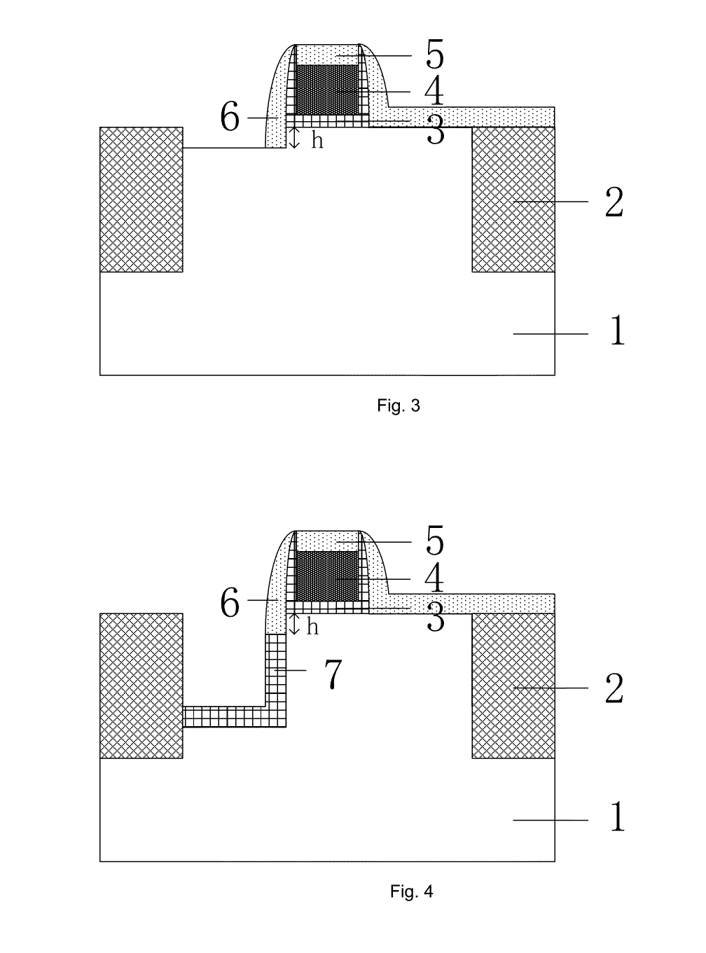

3. Exposing a pattern for source region by photolithography, anisotropically etching, with an etching depth of 10 nm, the silicon of source region using the gate sidewall as a protection layer, and removing a photoresist; then depositing Si₃N₄ with a thickness of 50-100 nm, exposing again the source region by photolithography, anisotropically etching Si₃N₄ to form a single side oxidation resistant sidewall 6, and removing a photoresist, as shown in FIG. 3.

4. Further anisotropically etching, with an etching depth is 20-100 nm, the silicon of the source region to form a recessed silicon trench structure using Si₃N₄ for protection; then oxidizing the exposed silicon to form a SiO₂ layer, that is, a insulating layer 7, wherein the SiO₂ layer has a thickness of 50-100 nm, as shown in FIG. 4.

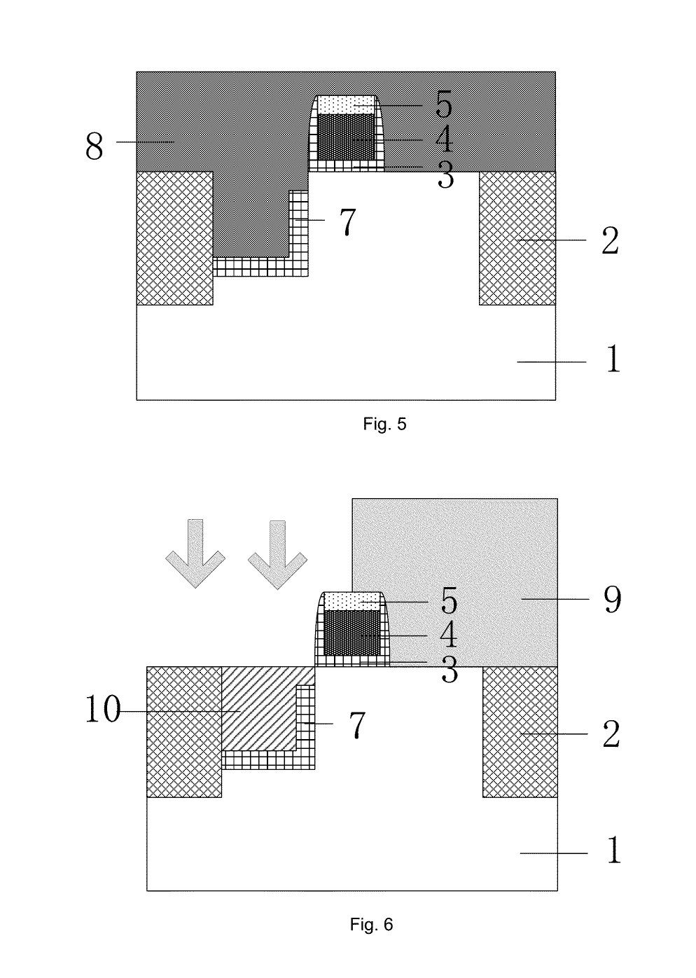

5. Depositing a thick layer of polysilicon material 8 by LPCVD, as shown in FIG. 5. performing a chemical mechanical polishing (CMP) to the polysilicon by using the hard mask on the top of the gate region as a stop layer, and overetching the polysilicon till the surface of a channel to form a polysilicon source structure.

6. Exposing the source region by photolithography, and performing P⁺ ion implantation by using a photoresist 9 and the gate region as a mask to form a highly-doped source region 10, wherein an ion implanting energy is 40 keV, and an implanting impurity is BF²⁺, as shown in FIG. 6.

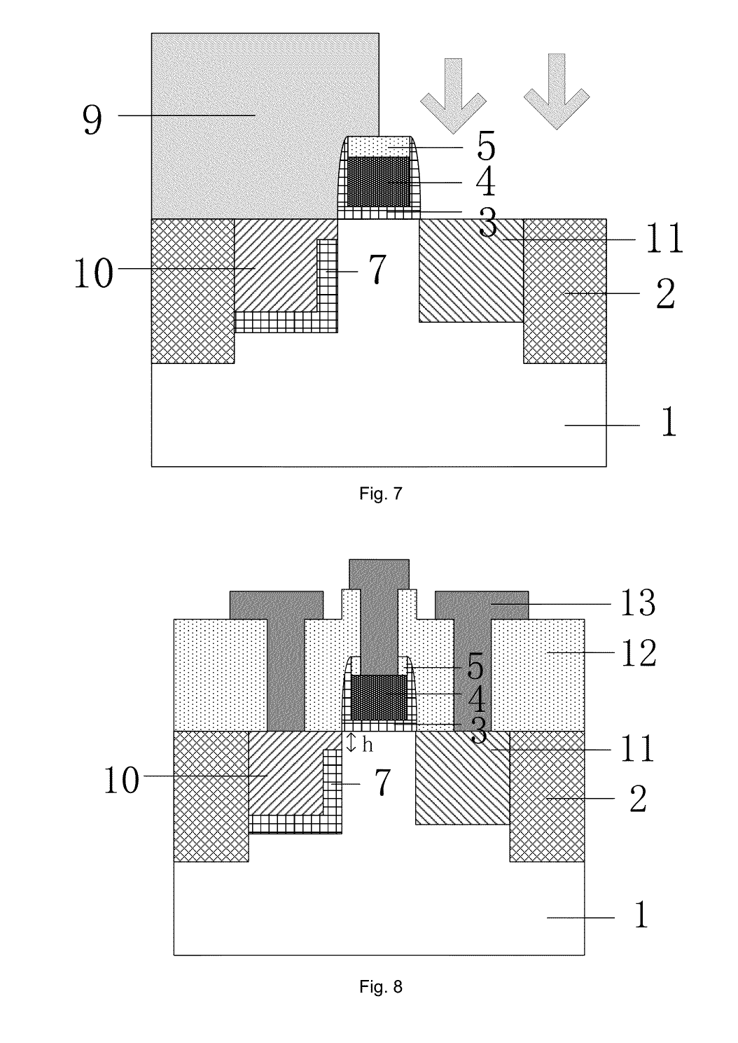

7. Exposing a drain region by photolithography, and performing N ion implantation by using a photoresist 9 and a gate region as a mask to form a lowly-doped drain region 11, where an ion implanting energy is 50 keV and an implanting impurity is As⁺, as shown in FIG. 7; and performing once rapid high temperature annealing to activate the doped impurities for source/drain.

8. Finally proceeding to a general CMOS Back-End-Of-Line, comprising depositing a passivation layer, opening contact hole, and performing metallization, so that the tunneling transistor is prepared, as shown in FIG. 8.

Although the present invention has been described with respect to the preferred embodiment as above, however, it is not intended to limit the present invention. Without departing from the scope of the present invention technical solution, using the technical method and technical contents disclosed above, Various changes and modifications for the present technical solution may be made or equivalent embodiments may be obtained by those skilled in the art in view of the method and technical contents disclosed above, without departing from the scope of the present invention. Therefore, any simple changes, equivalent changes and modifications made to the above embodiments according to the present invention technical spirit without departing from the spirit of the present invention all falls into the protection scope of the present invention.

What is claimed is:

1. A tunneling transistor, comprising a high resistance semiconductor substrate (1), a highly-doped source region (10), a lowly-doped drain region (11), a gate dielectric layer (3), and a control gate (4), where a tunneling junction of the tunneling transistor is formed between the highly-doped source region (10) and a channel and has a thickness h of 5-10 nm, wherein an insulating layer (7) is provided between the highly-doped source region (10) and the high resistance semiconductor substrate (1) under the tunneling junction and has a thickness of 50-500 nm, and the highly-doped source region (10) and the lowly-doped drain region (11) have the doping types opposite to each other, where for a N-type transistor, the highly-doped P⁺ source region has a doping concentration between 5×10¹⁹cm⁻³ and 1×10²¹cm⁻³, and the lowly-doped N drain region has a doping concentration between 1×10¹⁸cm⁻³ and 1×10¹⁹cm⁻³; for a P-type transistor, the highly-doped N⁺ source region has a doping concentration between 5×10¹⁹cm⁻³ and 1×10²¹cm⁻³, the lowly-doped P drain region has a doping concentration between 1×10¹⁸cm⁻³ and 1×10¹⁹cm⁻³.

2. The tunneling transistor according to claim 1, wherein the high resistance semiconductor (1) is lightly doped, with the same doping type as that of the highly-doped source region (10), and has a doping concentration less than 1×10¹⁷cm⁻³.

3. A method of inhibiting a leakage current of a tunneling transistor, a tunneling junction being formed at an interface between a source region and a channel of the tunneling transistor, wherein providing an insulating layer between a highly-doped source region and high resistance semiconductor substrate under the tunneling junction, the insulating layer having a thickness of 50-500 nm, so that the leakage current from a source-to-drain direct tunneling in the tunneling transistor is inhibited using the insulating layer.

4. A preparation method of the tunneling transistor according to claim 1, comprising the steps of:
(1) defining an active region by shallow trench isolation in a high resistance semiconductor substrate;
(2) growing a gate dielectric layer, and depositing a control gate material and a hard mask layer;
(3) Performing photolithography and etching to form a pattern for control gate, and using sidewall process to form a layer of thin sidewall protection structure, wherein a thickness of the thin sidewall determines the distance from a source junction to the edge of the control gate;
(4) exposing a source region by photolithography, anisotropically etching, with an etching depth as a thickness h of the tunneling junction, the silicon of the source region using the gate sidewall as a protection layer; then depositing an oxidation resistant material, performing photolithography to expose source region again, anisotropically etching the oxidation resistant material to form a single side oxidation resistant sidewall;
(5) further anisotropically etching the silicon in the source region to form a recessed silicon trench structure using the oxidation resistant sidewall for protection; oxidizing the exposed silicon to form an insulating layer;
(6) removing an oxidation resistant layer, then depositing a source material, and overetching the source material till the surface of a channel;
(7) exposing the source region by photolithography, and forming a highly-doped source region by performing ion implantation using photoresist and the control gate as a mask; then exposing the drain region by photolithography, and forming a lowly-doped drain region with the other doping type by performing ion implantation using photoresist and the control gate as a mask; and then performing rapid annealing to activate the doped impurities for source/drain;
(8) Finally proceeding to a CMOS Back-End-Of-Line, so that the tunneling transistor of claim 1 is prepared.

5. The preparation method according to claim 4, wherein a material for the semiconductor substrate in the step (1) is selected from a group consisting of Si, Ge, SiGe, GaAs and other binary or ternary compound semiconductor in II-VI, III-V and IV-VI groups, silicon on insulator and germanium on insulator.

6. The preparation method according to claim 4, wherein a material for the gate dielectric layer in the step (2) is selected from a group consisting of SiO₂, Si₃N₄, and high-K gate dielectric material.

7. The preparation method according to claim 4, wherein the control gate material in the step (2) is selected from a group consisting of doped polysilicon, metal cobalt, nickel and others metal or metal silicide.

8. The preparation method according to claim 4, wherein the source/drain material in the step (6) is selected from a group consisting of polysilicon, Ge, SiGe, GaAs, and the other binary or ternary compound semiconductor in II-VI, III-V and IV-IV groups.
